(19) United States
(12) Patent Application Publication
(10) Pub. No.: US 2004/0094095 A1
(43) Pub. Date: May 20, 2004

(54) Substrate holder assembly

(75) Inventors: Jen-Hung Huang, Kaoshing (TW); Cheng-Cong Yu, Bei Chie (TW); Wu-Xing Lin, Yunlin (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/300,859

(22) Filed: Nov. 19, 2002

(51) Int. Cl. H01L 21/306

(52) U.S. Cl. 118/728; 156/345.51

(57) ABSTRACT

A new and improved substrate holder assembly for supporting a substrate in a process chamber for the fabrication of semiconductor integrated circuits on the substrate. The substrate holder assembly comprises an annular shield which is fitted in the process chamber. A dish-shaped substrate holder extends through the center of the shield and includes a pair of outwardly-extending pin support flanges that are disposed beneath the shield. The substrate holder includes an annular substrate support shoulder for supporting the substrate. A substrate clamp of the substrate holder assembly includes a pair of downwardly-extending alignment pins which are inserted through respective pin openings in the shield and are supported by the respective pin support flanges. Accordingly, the alignment pins align and support the substrate clamp slightly above the substrate holder to prevent direct contact of the substrate clamp with the substrate holder thus, the formation of potential device-contaminating particles.

### FIELD OF THE INVENTION

The present invention relates to substrate holders for supporting substrates in a processing chamber such as a PVD (physical vapor deposition) chamber for the fabrication of integrated circuits on the substrate. More particularly, the present invention relates to a new and improved substrate holder assembly which prevents the formation of potential device-contaminating particles during assembly and disassembly of the substrate holder assembly.

### BACKGROUND OF THE INVENTION

In the fabrication of semiconductor integrated circuits, metal conductor lines are used to interconnect the multiple components in device circuits on a semiconductor wafer. A general process used in the deposition of metal conductor line patterns on semiconductor wafers includes deposition of a conducting layer on the silicon wafer substrate; formation of a photoresist or other mask such as titanium oxide or silicon oxide, in the form of the desired metal conductor line pattern, using standard lithographic techniques; subjecting the wafer substrate to a dry etching process to remove the conducting layer from the areas not covered by the mask, thereby leaving the metal layer in the form of the masked conductor line pattern; and removing the mask layer typically using reactive plasma and chlorine gas, thereby exposing the top surface of the metal conductor lines. Typically, multiple alternating layers of electrically conductive and insulative materials are sequentially deposited on the wafer substrate, and conductive layers at different levels on the wafer may be electrically connected to each other by etching vias, or openings, in the insulative layers and filling the vias using aluminum, tungsten or other metal to establish electrical connection between the conductive layers.

Laser marks are typically embedded in the substrate at the beginning of processing. The laser marks contain certain information necessary for later identification of the substrate, such as lot number and job number. These marks must be kept visible during wafer processing. For some substrates, the laser marks are located in the saw kerf adjacent to the integrated circuit dice, in which case the marks identify locations of die on the substrate. For other substrates, only one set of laser marks are provided on each substrate, typically in a region where integrated circuit die cannot be fabricated, such as adjacent to the edge of the substrate.

In semiconductor production, the quality of the integrated circuits on the semiconductor wafer is directly correlated with the purity of the fabricating processes, which in turn depends upon the cleanliness of the manufacturing environment. Furthermore, technological advances in recent years in the increasing miniaturization of semiconductor circuits necessitate correspondingly stringent control of impurities and contaminants in the plasma process chamber. When the circuits on a wafer are submicron in size, the smallest quantity of contaminants can significantly reduce the yield of the wafers. For instance, the presence of particles during deposition or etching of thin films can cause voids, dislocations, or short-circuits which adversely affect performance and reliability of the devices constructed with the circuits.

Particle and film contamination has been significantly reduced in the semiconductor industry by improving the quality of clean rooms, by using automated equipment designed to handle semiconductor substrates, and by improving techniques used to clean the substrate surfaces. However, as deposit of material on the interior surfaces of the processing chamber remains a problem, various techniques for in-situ cleaning of process chambers have been developed in recent years. Cleaning gases such as nitrogen trifluoride, chlorine trifluoride, hexafluoroethane, sulfur hexafluoride and carbon tetrafluoride and mixtures thereof have been used in various cleaning applications. These gases are introduced into a process chamber at a predetermined temperature and pressure for a desirable length of time to clean the surfaces inside a process chamber. However, these cleaning techniques are not always effective in cleaning or dislodging all the film and particle contaminants coated on the chamber walls and interior chamber components. The smallest quantity of contaminants remaining in the chamber after such cleaning processes can cause significant problems in subsequent manufacturing cycles.

Deposition of conductive layers on the wafer substrate can be carried out using any of a variety of techniques. These include oxidation, LPCVD (low-pressure chemical vapor deposition), APCVD (atmospheric-pressure chemical vapor deposition), and PECVD (plasma-enhanced chemical vapor deposition). In general, chemical vapor deposition involves reacting vapor-phase chemicals that contain the required deposition constituents with each other to form a nonvolatile film on the wafer substrate. Chemical vapor deposition is the most widely-used method of depositing films on wafer substrates in the fabrication of integrated circuits on the substrates.

Physical vapor deposition (PVD) is another technique used in the deposition of conductive layers, particularly metal layers, on a substrate. Physical vapor deposition includes techniques such as filament evaporation and electron beam evaporation and, most recently, sputtering. In a sputtering process, high-energy particles strike a solid slab of high-purity target material and physically dislodge atoms from the target. The sputtered atoms are deposited on the substrate.

FIG. 1 illustrates a typical standard physical vapor deposition chamber 10, such as an ENDURA PVD system available from Applied Materials, Inc., of Santa Clara, Calif. The PVD chamber 10 includes a chamber wall 12 which defines a chamber interior 14. A metal target 20 is disposed beneath a cathode 18 in the top of the chamber interior 14. An annular shield 24 typically extends from the inner surface of the chamber wall 12. A hoop assembly 22, which is encircled by the shield 24 in the chamber interior 14, supports a substrate 34 above a substrate heater 16 that heats the substrate 34 during processing.

The hoop assembly 22 includes a typically stainless steel hoop 26, on which is supported a clamp 30 provided with an annular contact rim 31, as shown in FIG. 2, and having a central opening 32. As further shown in FIG. 2, the hoop 26 includes a sloped clamp support surface 27 on which the contact rim 31 of the clamp 30 rests. The substrate 34 rests beneath the clamp 30, on an annular substrate support shoulder 28 provided in the hoop 26, and is exposed to the chamber interior 14 through the central opening 32 of the clamp 30. The clamp 30 functions to hold the substrate 34 in place in the hoop assembly 22 when argon backside pressure is applied to the substrate 34 during processing.

In a typical physical vapor deposition (PVD) process, the substrate 34 is supported in the hoop assembly 22, above the substrate heater 16, and nitrogen gas and an inert gas (typically argon) enter the chamber interior 14 through a gas inlet (not shown). A power supply (not shown) applies a negative potential to the metal target 20, and the substrate 34 functions as an anode having a net positive charge. Consequently, an electric field is created in the chamber interior 14, and a plasma is generated from the nitrogen and inert gas. A high density of positive ions from the plasma is strongly attracted to the negative target material, striking the target at high velocity. The metal atoms are sputtered, or knocked off, the metal target 20 and scatter in the chamber interior 14, reacting with nitrogen atoms and nitrogen ions formed in the plasma to produce metal nitride particles. Some of the metal nitride particles are deposited on the substrate 30, where the atoms nucleate and form a thin film. The shield 24 prevents films from forming on the interior surfaces of the chamber wall 12.

As shown in FIG. 2, one of the problems inherent in the conventional hoop assembly 22 is that the contact rim 31 of the clamp 30 is provided in direct contact with the clamp support surface 27 of the hoop 26. This frequently forms metal particles 36 which dislodge from the clamp support surfaces 27 when the clamp 30 is placed on the hoop 36 and/or removed from the hoop 36. After processing, when the clamp 30 is removed from the hoop 26 in order to remove the substrate 34 from the chamber interior 14, these particles 36 have a tendency to drop on the surface of the substrate 34 and contaminate devices being fabricated on the substrate 34. Accordingly, a new and improved wafer holder assembly having a design which prevents the formation of substrate-contaminating particles is needed for supporting substrates in a processing chamber.

An object of the present invention is to provide a new and improved substrate holder assembly for supporting a substrate in a processing chamber.

Another object of the present invention is to provide a new and improved substrate holder assembly which prevents or reduces the formation of potential device-contaminating particles particularly during assembly and disassembly of the substrate holder assembly.

Still another object of the present invention is to provide a substrate holder assembly which includes a substrate holder for supporting a substrate in a processing chamber and a substrate clamp which is disposed in spaced-apart relationship with respect to the substrate holder to prevent or reduce particle formation which may otherwise result from direct contact of the substrate clamp with the substrate holder.

Yet another object of the present invention is to provide a substrate holder assembly which enhances the yield of devices on a substrate.

Another object of the present invention is to provide a substrate holder assembly which reduces or eliminates friction or contact between parts in order to prevent the formation of potential device-contaminating particles particularly upon assembly and/or disassembly of the substrate holder assembly.

A still further object of the present invention is to provide a substrate holder assembly having a clamp alignment mechanism which is sufficiently located with respect to a substrate to prevent potential device-contaminating particles from contaminating the substrate particularly upon assembly and disassembly of the substrate holder assembly.

### SUMMARY OF THE INVENTION

In accordance with these and other objects and advantages, the present invention is generally directed to a new and improved substrate holder assembly for supporting a substrate in a process chamber for the fabrication of semiconductor integrated circuits on the substrate. The substrate holder assembly comprises an annular shield which is fitted in the process chamber. A dish-shaped substrate holder extends through the center of the shield and includes a pair of outwardly-extending pin support flanges that are disposed beneath the shield. The substrate holder includes an annular substrate support shoulder for supporting the substrate. A substrate clamp of the substrate holder assembly includes a pair of downwardly-extending alignment pins which are inserted through respective pin openings in the shield and are supported by the respective pin support flanges. Accordingly, the alignment pins align and support the substrate clamp slightly above the substrate holder to prevent direct contact of the substrate clamp with the substrate holder and thus, contact-induced formation of potential device-contaminating particles during assembly and disassembly of the substrate holder assembly.

### BRIEF DESCRIPTION OF THE DRAWINGS

The invention will now be described, by way of example, with reference to the accompanying drawing, in which:

FIG. 1 is a sectional view of a typical conventional PVD process chamber, with a conventional hoop assembly mounted in the chamber;

FIG. 2 is an enlarged sectional view, taken along section line 2 in FIG. 1, of the clamp and hoop elements of the conventional hoop assembly, more particularly illustrating formation of particles caused by direct contact of the clamp with the hoop;

FIG. 3 is a sectional view of an illustrative embodiment of the substrate holder assembly of the present invention;

FIG. 4 is an exploded, sectional view, illustrating assembly of the substrate holder assembly of the present invention; and

FIG. 5 is an enlarged sectional view, taken along section line 5 in FIG. 3, of the substrate clamp and substrate holder elements of the substrate holder assembly of the present invention, with the substrate clamp supported above and out of direct contact with the substrate holder.

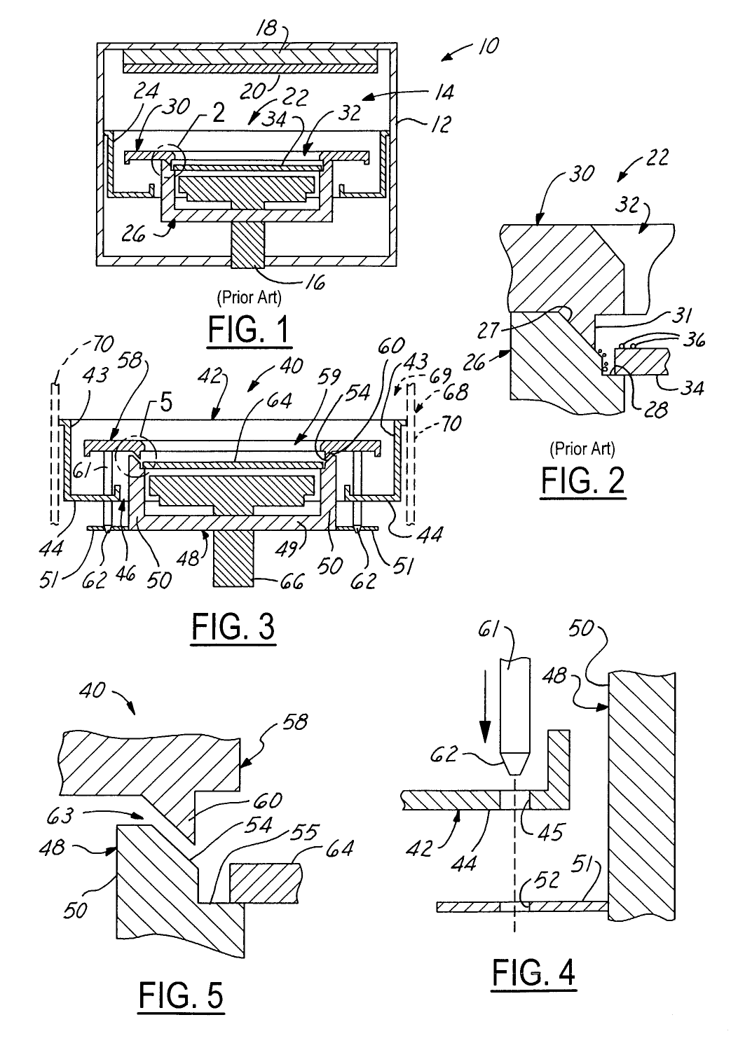

### DESCRIPTION OF THE PREFERRED EMBODIMENTS

The present invention has particularly beneficial utility in supporting a substrate in a PVD (physical vapor deposition) chamber while preventing the formation of contact-induced particles which otherwise may lead to contamination of devices on the substrate. However, the invention is not so limited in application, and while references may be made to such PVD chamber, it is understood that the invention is more generally applicable to supporting substrates in a variety of process chambers and may be capable of use in a variety of industrial and mechanical applications.

The substrate holder assembly 40 of the present invention typically includes a generally pan-shaped shield 42 which is fitted in the chamber interior 69 of a process chamber 68, such as an ENDURA PVD chamber available from Applied Materials, Inc., of Santa Clara, Calif., for example. However, it is understood that the process chamber 69 may be any alternative type of process chamber to which the present invention may be applicable. The shield 42 may include an annular, vertical shield wall 43 which is attached to the interior surface of the chamber wall 70 and an annular, horizontal shield bottom 44 which extends inwardly from the shield wall 43. The shield bottom 44 defines a central shield opening 46 in the shield 42. At least two pin openings 45, one of which is shown in FIG. 4, extend through the shield bottom 44, the purpose of which pin openings 45 will be hereinafter described.

A substrate holder 48 of the substrate holder assembly 40 typically has a generally dish-shaped configuration, and may include a circular, horizontal holder bottom 49 and an annular, vertical holder wall 50 which extends upwardly from the holder bottom 49. The holder bottom 49 may be mounted to a substrate heater 66 in the chamber interior 69, in conventional fashion, or the substrate holder 48 may be otherwise mounted in the chamber interior 69 according to the knowledge of those skilled in the art. A continuous, annular pin support flange 51 extends horizontally outwardly from the substrate holder 48. As shown in FIG. 4, the pin support flange 51 includes at least two pin seats 52 which are disposed in vertical alignment with respect to the respective pin openings 45 in the shield bottom 44 of the shield 42. In an alternative embodiment, at least two discrete pin support flanges 51 extend from the substrate holder 48, in which case each of the pin support flanges 51 is provided with a pin seat 52 that is disposed in vertical alignment with respect to the corresponding pin opening 45 in the shield bottom 44 of the shield 42.

As shown in FIG. 5, an annular, sloped or beveled surface 54 is provided in the upper edge of the holder wall 50 of the substrate holder 48. An annular, horizontal substrate support shoulder 55 is further provided in the holder wall 50, adjacent to the beveled surface 54. Accordingly, as shown in FIG. 3, the substrate support shoulder 55 is adapted for supporting a substrate 64 in a horizontal position above the substrate heater 66 in the chamber interior 69, as hereinafter further described.

The substrate holder assembly 40 further includes a substrate clamp 58 which is provided with a central clamp opening 59, circumscribed by a downwardly-protruding, annular clamp rim 60. At least two alignment pins 61 extend downwardly from the bottom surface of the substrate clamp 58. Each of the alignment pins 61 may have a tapered pin tip 62 which is designed to mate with the corresponding companion pin seat 52 (FIG. 4) in the pin support flange 51. Accordingly, as shown in FIGS. 3 and 4, the downwardly-extending alignment pins 61 are capable of extension through the respective pin openings 45 in the shield bottom 44 of the shield 42 until the tapered pin tip 62 of each alignment pin 61 seats in the pin seat 52 in the pin support flange or flanges 51. The length of each alignment pin 61 is selected such that the substrate clamp 58 is supported above, rather than in contact with, the underlying substrate holder 48 when the alignment pins 61 are seated in the respective pin seats 52. Accordingly, as shown in FIG. 5, when the substrate clamp 58 is in place in the assembled substrate holder assembly 40, a space 63 is defined between the downwardly-extending, annular clamp rim 60 of the substrate clamp 58 and the beveled surface 54 of the substrate holder 48. While the substrate holder assembly 40 shown in FIG. 3 includes at least two alignment pins 61 which extend through respective pin openings 45 provided in the shield bottom 44 and seat in the respective pin seats 52 in the pin support flange or flanges 51, it is understood that the pin support flange or flanges 51 may be omitted and the alignment pins 61 may be supported by the shield bottom 44 of the shield 42. In that case the shield 42, rather than the pin support flange or flanges 51, would serve as the support for the substrate clamp 58 and would maintain the substrate clamp 58 in spaced-apart relationship with respect to the substrate holder 48. The present invention further contemplates that the substrate clamp 58 may be supported by the shield wall 43 or any other element of the shield 42.

Referring again to FIGS. 3-5, in application of the substrate holder assembly 40, the substrate 64 is initially supported on the annular substrate support shoulder 55 of the substrate holder 48, above the substrate heater 66. Next, the substrate clamp 58 is lowered in place above the substrate holder 48 to secure the substrate 64 in the substrate holder assembly 40 and hold the substrate 64 in place in the event that argon gas pressure is applied to the backside of the substrate 64 during processing, for example. Installation of the substrate clamp 58 is accomplished by initially inserting the alignment pins 61 through the respective pin openings 45 in the shield 42 and then lowering the tapered pin tips 62 to seat in the respective pin seats 52 in the pin support flange or flanges 51. As shown in FIG. 5, due to the space 63 between the clamp rim 60 of the substrate clamp 58 and the beveled surface 54 of the substrate holder 48, the substrate clamp 58 remains out of contact with the clamp support surface 54 as the PVD or other process is carried out in the process chamber 68. Therefore, potential device-contaminating particles are incapable of becoming scraped or dislodged from the clamp rim 60, the beveled surface 54, or both, as a result of such contact and falling on the surface of the substrate 64 and contaminating devices being fabricated thereon.

While the preferred embodiments of the invention have been described above, it will be recognized and understood that various modifications can be made in the invention and the appended claims are intended to cover all such modifications which may fall within the spirit and scope of the invention.

What is claimed is:

1. A substrate holder assembly comprising:
a substrate holder for holding a substrate;
a support disposed adjacent to said substrate holder;
a substrate clamp for engaging said support; and
wherein said substrate clamp is disposed in substantially non-contacting relationship with said substrate holder when said substrate clamp engages said support.

2. The substrate holder assembly of claim 1 wherein said support comprises at least one pin support flange carried by said substrate holder.

3. The substrate holder assembly of claim 1 further comprising at least two alignment pins carried by said substrate clamp for engaging said support.

4. The substrate holder assembly of claim 3 wherein said support comprises at least one pin support flange carried by said substrate holder.

5. The substrate holder assembly of claim 1 further comprising a beveled surface provided in said substrate holder and an annular clamp rim carried by said substrate clamp for positioning in spaced-apart relationship to said beveled surface.

6. The substrate holder assembly of claim 5 wherein said support comprises at least one pin support flange carried by said substrate holder.

7. The substrate holder assembly of claim 5 further comprising at least two alignment pins carried by said substrate clamp for engaging said support.

8. The substrate holder assembly of claim 7 wherein said support comprises at least one pin support flange carried by said substrate holder.

9. The substrate holder assembly of claim 2 wherein said at least one pin support flange has a generally annular configuration.

10. The substrate holder assembly of claim 9 further comprising at least two alignment pins carried by said substrate clamp for engaging said at least one pin support flange.

11. The substrate holder assembly of claim 9 further comprising a beveled surface provided in said substrate holder and an annular clamp rim carried by said substrate clamp for positioning in spaced-apart relationship to said beveled surface.

12. The substrate holder assembly of claim 11 further comprising at least two alignment pins carried by said substrate clamp for engaging said at least one pin support flange.

13. A substrate holder assembly comprising:
an annular shield having at least two pin openings;
a substrate holder for holding a substrate provided in said shield;
a support disposed beneath said shield;
a substrate clamp;
at least two alignment pins extending from said substrate clamp for extension through said at least two pin openings, respectively, in said shield and engaging said support for spacing said substrate clamp with respect to said substrate holder.

14. The substrate holder assembly of claim 13 wherein said support comprises at least one pin support flange carried by said substrate holder.

15. The substrate holder assembly of claim 13 further comprising a beveled surface provided in said substrate holder and an annular clamp rim carried by said substrate clamp for positioning in spaced-apart relationship to said beveled surface.

16. The substrate holder assembly of claim 15 wherein said support comprises at least one pin support flange carried by said substrate holder.

17. A substrate holder assembly comprising:
an annular shield having at least two pin openings;
a substrate holder for holding a substrate provided in said shield;
a support having at least two pin seats disposed beneath said shield;
a substrate clamp;
at least two alignment pins extending from said substrate clamp for extension through said at least two pin openings, respectively, in said shield and engaging said at least two pin seats, respectively, for spacing said substrate clamp with respect to said substrate holder.

18. The substrate holder assembly of claim 17 wherein said support comprises at least one pin support flange carried by said substrate holder.

19. The substrate holder assembly of claim 17 further comprising a beveled surface provided in said substrate holder and an annular clamp rim carried by said substrate clamp for positioning in spaced-apart relationship to said beveled surface.

20. The substrate holder assembly of claim 19 wherein said support comprises at least one pin support flange carried by said substrate holder.
